(19) United States
(12) Patent Application Publication
(10) Pub. No.: US 2012/0012865 A1
(43) Pub. Date: Jan. 19, 2012

(54) LED ARRAY PACKAGE WITH A HIGH THERMALLY CONDUCTIVE PLATE

(76) Inventors: Jianhua Li, Livermore, CA (US); Rene Helbing, Livermore, CA (US); David Hum, Livermore, CA (US)

(21) Appl. No.: 12/838,686

(22) Filed: Jul. 19, 2010

(51) Int. Cl. H01L 33/48; H01L 33/44

(52) U.S. Cl. 257/88; 257/99; 257/E33.058; 257/98; 257/E33.061

(57) ABSTRACT

A light source includes a substrate, a light emitting diode on the substrate, and a plate supporting member attached to the substrate and surrounding the light emitting diode to form a cavity. In addition, the light source includes a plate on the plate supporting member such that a distance between the plate and the substrate is approximately less than or equal to 1 mm. Furthermore, the light source includes a phosphor layer on the plate opposite the cavity.

### BACKGROUND

1. Field

The present disclosure relates to a light emitting diode (LED) array package and, more particularly, to an LED array package with a highly thermal conductive plate.

2. Description of Related Art

LEDs have been developed for many years and have been widely used in various light applications. As LEDs are light-weight, consume less energy, and have a good electrical power to light conversion efficiency, they have been used to replace conventional light sources, such as incandescent lamps and fluorescent light sources. LEDs may be utilized in an array package. For LED array packages, the temperature of a top surface of the package can reach 200° C. or more, which can damage the device. An LED array package for producing white light is typically made by dispensing a mixture of phosphor and silicone on top of a blue LED die array. In mass production, the dispensed mixture varies in each package, and therefore color and light output also vary for each package. As such, there is a need in the art to improve the heat dissipation performance, color consistency, and flux consistency of LED array packages.

### SUMMARY

In an aspect of the disclosure, a light source includes a substrate, a light emitting diode on the substrate, and a plate supporting member attached to the substrate and surrounding the light emitting diode to form a cavity. In addition, the light source includes a plate on the plate supporting member such that a distance between the plate and the substrate is approximately less than or equal to 1 mm. Furthermore, the light source includes a phosphor layer on the plate opposite the cavity.

In an aspect of the disclosure, a light source includes a substrate, a light emitting diode on the substrate, and a means for supporting a plate. The means for supporting a plate is attached to the substrate to form a cavity around the light emitting diode. In addition, the light source includes a plate on the means for supporting a plate such that a distance between the plate and the substrate is approximately less than or equal to 1 mm. Furthermore, the light source includes a phosphor layer on the plate opposite the cavity.

### BRIEF DESCRIPTION OF THE DRAWINGS

FIG. 1 is a cross-section view of a first exemplary LED array package.

FIG. 2 is a cross-section view of a second exemplary LED array package.

FIG. 3 is a cross-section view of a third exemplary LED array package.

### DETAILED DESCRIPTION

Various aspects of the present invention will be described herein with reference to drawings that are schematic illustrations of idealized configurations of the present invention. As such, variations from the shapes of the illustrations as a result, for example, manufacturing techniques and/or tolerances, are to be expected. Thus, the various aspects of the present invention presented throughout this disclosure should not be construed as limited to the particular shapes of elements (e.g., regions, layers, sections, substrates, etc.) illustrated and described herein but are to include deviations in shapes that result, for example, from manufacturing. By way of example, an element illustrated or described as a rectangle may have rounded or curved features and/or a gradient concentration at its edges rather than a discrete change from one element to another. Thus, the elements illustrated in the drawings are schematic in nature and their shapes are not intended to illustrate the precise shape of an element and are not intended to limit the scope of the present invention.

It will be understood that when an element such as a region, layer, section, substrate, or the like, is referred to as being “on” another element, it can be directly on the other element or intervening elements may also be present. In contrast, when an element is referred to as being “directly on” another element, there are no intervening elements present. It will be further understood that when an element is referred to as being “formed” on another element, it can be grown, deposited, etched, attached, connected, coupled, or otherwise prepared or fabricated on the other element or an intervening element. In addition, when a first element is “coupled” to a second element, the first element may be directly connected to the second element or the first element may be indirectly connected to the second element with intervening elements between the first and second elements.

Furthermore, relative terms, such as “lower” or “bottom” and “upper” or “top,” may be used herein to describe one element's relationship to another element as illustrated in the drawings. It will be understood that relative terms are intended to encompass different orientations of an apparatus in addition to the orientation depicted in the drawings. By way of example, if an apparatus in the drawings is turned over, elements described as being on the “lower” side of other elements would then be oriented on the “upper” side of the other elements. The term “lower” can therefore encompass both an orientation of “lower” and “upper,” depending of the particular orientation of the apparatus. Similarly, if an apparatus in the drawing is turned over, elements described as “below” or “beneath” other elements would then be oriented “above” the other elements. The terms “below” or “beneath” can therefore encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Various aspects of an LED array package may be illustrated with reference to one or more exemplary configurations. As used herein, the term “exemplary” means “serving as an example, instance, or illustration,” and should not necessarily be construed as preferred or advantageous over other configurations of an LED array package disclosed herein. Furthermore, various descriptive terms used herein, such as “on” and “transparent,” should be given the broadest meaning possible within the context of the present disclosure. For example, when a layer is said to be “on” another layer, it should be understood that that one layer may be deposited, etched, attached, or otherwise prepared or fabricated directly or indirectly above or below that other layer. In addition, something that is described as being “transparent” should be understood as having a property allowing no significant obstruction or absorption of electromagnetic radiation in the particular wavelength (or wavelengths) of interest, unless a particular transmittance is provided.

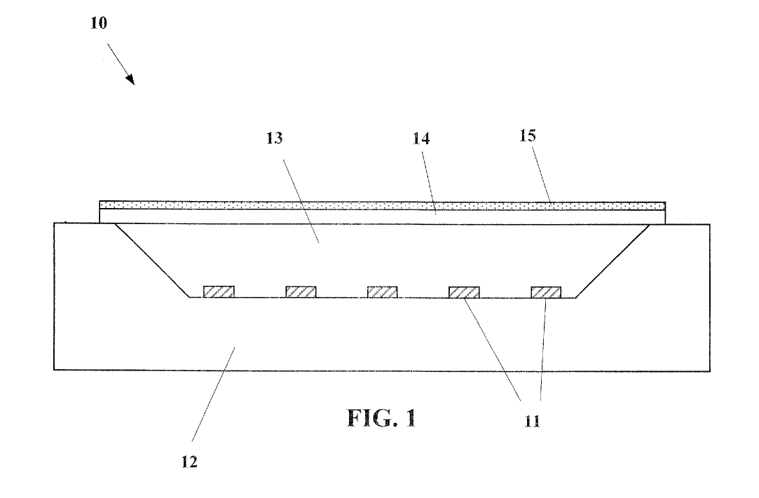

FIG. 1 is a cross-section view of a first exemplary LED array package 10. An LED is a semiconductor material impregnated, or doped, with impurities. These impurities add “electrons” and “holes” to the semiconductor, which can move in the material relatively freely. Depending on the kind of impurity, a doped region of the semiconductor can have predominantly electrons or holes. A doped region with electrons may be referred to as an n-type semiconductor region. A doped region with holes may be referred to as a p-type semiconductor region. In LED applications, the semiconductor includes an n-type semiconductor region, a p-type semiconductor region, and an intervening active region between the n-type and p-type semiconductor regions. When a forward voltage sufficient to overcome the reverse electric field is applied across the p-n junction, electrons and holes are forced into the active region and combine. When electrons combine with holes, they fall to lower energy levels and release energy in the form of light.

The light source may be configured to produce white light. White light may enable the light source to act as a direct replacement for conventional light sources used today in incandescent and fluorescent light sources. There are at least two common ways for producing white light. One way is to use individual LEDs that emit red, green, and blue, and then mix all the colors to produce white light. Another way is to use a phosphor material to convert monochromatic light emitted from a blue or ultra-violet (UV) LED to broad-spectrum white light. The present invention, however, may be practiced with other LED and phosphor combinations to produce different color light.

As shown in FIG. 1, an array of LEDs 11 is on substrate 12. The array of LEDs 11 may be covered with a layer 13 of silicone. A highly thermal conductive and transparent plate 14 is attached to a top surface of the LED array package 10 on the silicone layer 13. The plate 14 may be a sapphire plate, a silicon carbide (SiC) plate, a chemical-vapor-deposition (CVD) diamond plate, CVD SiC on a glass plate, CVD diamond on a glass plate, a glass plate, a zinc oxide (ZnO) plate, a quartz crystal plate, or any of the aforementioned types of plates with a metal net as described in U.S. patent application Ser. No. 12/487,453, entitled “LED Array Package Covered with a Highly Thermal Conductive Plate” and which is herein incorporated by reference. A phosphor layer 15 is coated on the plate 14. In production, the clear silicone 13 may be applied on the die array 11 and the phosphor layer 15 may be coated onto the plate 14. The phosphor coated plate 14 may then be placed on top of and cured together with the clear silicone layer 13.

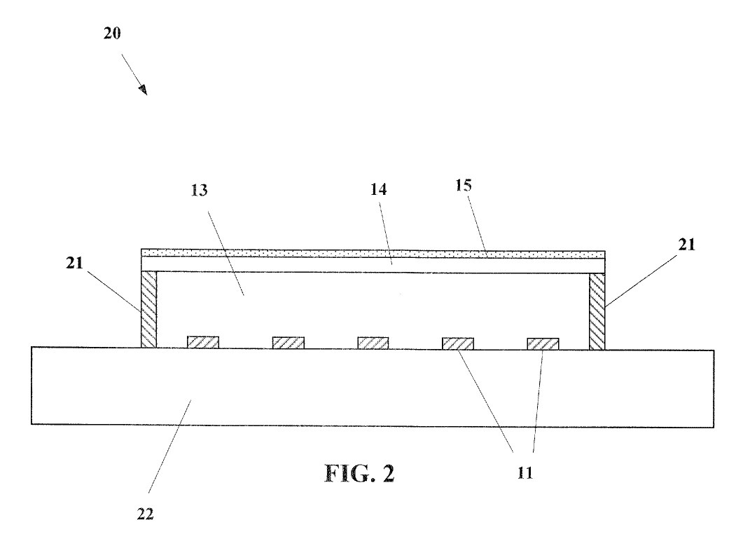

FIG. 2 is a cross-section view of a second exemplary LED array package 20. As shown in FIG. 2, an array of LEDs 11 is on the substrate 22. A thermally conductive ring 21 such as a metal ring surrounds the array of LEDs 11 and is attached to the substrate 22. Clear silicone 13 is dispensed within the ring 21. Phosphor 15 is layered onto the plate 14 and the phosphor coated plate 14 is located on top of the clear silicone 13 and ring 21.

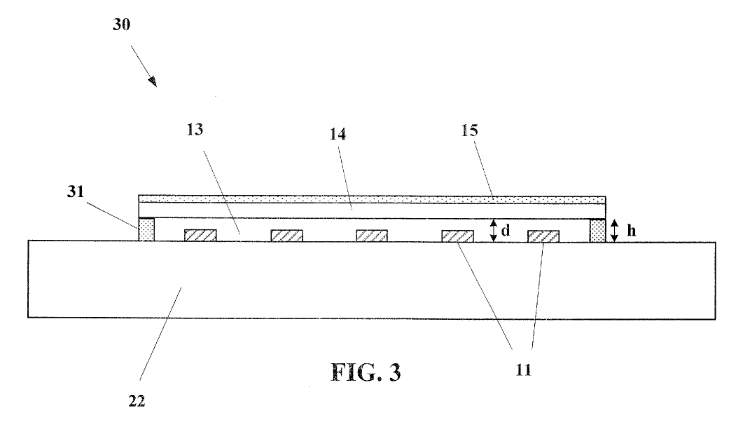

FIG. 3 is a cross-section view of a third exemplary LED array package 30. As shown in FIG. 3, an array of LEDs 11 is on the substrate 22. The LEDs 11 may emit blue light. A means for supporting a plate 31 is attached to the substrate 22 and surrounds the array of LEDs 11 to form a cavity around the LEDs 11. The means for supporting a plate 31 is a plate supporting member, which may be a ring-shaped vertical member that extends approximately perpendicular to the substrate. The ring 31 may be thermally resistive. For example, the ring 31 may be formed of silicon. As used herein, “thermally resistive” corresponds to a thermal resistance greater than a thermal resistance of metal or a thermal conductivity less than a thermal conductivity of metal. Clear silicone 13 is dispensed within the cavity formed by the ring 31. Phosphor 15 is layered onto the plate 14 and the phosphor coated plate 14 is located on top of the clear silicone 13 and the ring 31. The phosphor coated plate 14 may be attached to the ring 31 or otherwise cured to the silicone layer 13 and the ring 31. In this configuration, when the ring 31 does not have a high thermal conductivity, the ring 31 has a height h that is less than or equal to 1 mm such that a distance d between the substrate 22 and the plate 14 is less than or equal to 1 mm. In another configuration, the height h of the ring is less than or equal to 0.5 mm such that the distance d between the substrate 22 and the plate 14 is less than or equal to 0.5 mm.

Having a short distance between the substrate 22 and the plate 14 allows the silicone layer 13 to be thin. A thin silicone layer 13 prevents overheating of the phosphor. The LED array package 30 provides better color and flux consistency, as the thickness of the phosphor coating can be better controlled than when the phosphor is dispensed in a silicone/phosphor mixture over the array of LEDs 11. In addition, wire bonds on the dies can be well protected by the plate 14. Furthermore, the LED array package 30 provides better ray mixing on the phosphor layer and is therefore a more uniform light source. Lastly, the LED array package 30 provides more light output with less thermal degradation.

The various aspects of this disclosure are provided to enable one of ordinary skill in the art to practice the present invention. Modifications to various aspects of an LED array package presented throughout this disclosure will be readily apparent to those skilled in the art, and the concepts disclosed herein may be extended to other applications. Thus, the claims are not intended to be limited to the various aspects of an LED array package presented throughout this disclosure, but are to be accorded the full scope consistent with the language of the claims. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. A light source, comprising:
a substrate;
a light emitting diode on the substrate;
a plate supporting member attached to the substrate and surrounding the light emitting diode to form a cavity;
a plate on the plate supporting member such that a distance between the plate and the substrate is approximately less than or equal to 1 mm; and
a phosphor layer on the plate opposite the cavity.

2. The light source of claim 1, wherein the distance between the plate and the substrate is approximately less than or equal to 0.5 mm.

3. The light source of claim 1, wherein a height of the plate supporting member is approximately less than or equal to 1 mm.

4. The light source of claim 1, wherein a height of the plate supporting member is approximately less than or equal to 0.5 mm.

5. The light source of claim 1, wherein the plate supporting member is thermally resistive.

6. The light source of claim 5, wherein the plate supporting member is silicon.

7. The light source of claim 1, wherein the plate supporting member comprises a silicon ring-shaped vertical member extending approximately perpendicular to the substrate.

8. The light source of claim 1, wherein the plate is attached to a top surface of the plate supporting member.

9. The light source of claim 1, further comprising a silicone layer over the light emitting diode within the cavity.

10. The light source of claim 9, wherein the plate is cured to the silicone layer and the plate supporting member.

11. The light source of claim 1, wherein the plate is transparent.

12. The light source of claim 1, wherein the plate is a sapphire plate, a silicon carbide plate, a chemical-vapor-deposition diamond plate, chemical-vapor-deposition silicon carbide on a glass plate, chemical-vapor-deposition diamond on a glass plate, a glass plate, a zinc oxide plate, or a quartz crystal plate.

13. The light source of claim 1, further comprising at least one additional light emitting diode on the substrate; wherein said light emitting diode and said at least one additional light emitting diode are in an array on the substrate.

14. The light source of claim 13, wherein the light emitting diode and the one additional light emitting diode emit blue light.

15. A light source, comprising:
a substrate;
a light emitting diode on the substrate;
means for supporting a plate, the means for supporting a plate being on the substrate to form a cavity around the light emitting diode;
a plate on the means for supporting a plate such that a distance between the plate and the substrate is approximately less than or equal to 1 mm; and
a phosphor layer on the plate opposite the cavity.

16. The light source of claim 15, wherein the distance between the plate and the substrate is approximately less than or equal to 0.5 mm.

17. The light source of claim 15, wherein a height of the means for supporting a plate is approximately less than or equal to 1 mm.

18. The light source of claim 15, wherein a height of the means for supporting a plate is approximately less than or equal to 0.5 mm.

19. The light source of claim 15, wherein the means for supporting a plate is thermally resistive.

20. The light source of claim 19, wherein the means for supporting a plate is silicon.

21. The light source of claim 15, wherein the means for supporting a plate comprises a silicon ring-shaped vertical member extending approximately perpendicular to the substrate.

22. The light source of claim 15, wherein the plate is attached to a top surface of the means for supporting a plate.

23. The light source of claim 15, further comprising a silicone layer over the light emitting diode within the cavity.

24. The light source of claim 23, wherein the plate is cured to the silicone layer and the means for supporting a plate.

25. The light source of claim 15, wherein the plate is transparent.

26. The light source of claim 15, wherein the plate is a sapphire plate, a silicon carbide plate, a chemical-vapor-deposition diamond plate, chemical-vapor-deposition silicon carbide on a glass plate, chemical-vapor-deposition diamond on a glass plate, a glass plate, a zinc oxide plate, or a quartz crystal plate.

27. The light source of claim 15, further comprising at least one additional light emitting diode on the substrate; wherein said light emitting diode and said at least one additional light emitting diode are in an array on the substrate.

28. The light source of claim 27, wherein the light emitting diode and the one additional light emitting diode emit blue light.
